(19) United States
(12) Patent Application Publication
(10) Pub. No.: US 2026/0344408 A1
(43) Pub. Date: Oct. 29, 2026

(54) SUBSTRATE ARRANGEMENT, METHOD FOR PRODUCING AN ELECTRONIC ASSEMBLY, AND ELECTRONIC ASSEMBLY

(71) Applicant: Heraeus Electronics GmbH & Co. KG, Hanau (DE)

(72) Inventors: Frank KRÜGER, Hanau (DE); Stefanie STOICA, Hanau (DE); Andreas Steffen KLEIN, Hanau (DE)

(21) Appl. No.: 19/459,580

(22) Filed: Jan. 26, 2026

(30) Foreign Application Priority Data
Jan. 31, 2025 (EP) 25155317.8

(51) Int. Cl. H10W 20/41; H10W 20/00; H10W 20/44

(52) U.S. Cl. CPC H10W 20/435; H10W 20/063; H10W 20/4421

(57) ABSTRACT

A substrate arrangement for a method of producing an electronic assembly and an electronic assembly. The substrate arrangement includes a metal foil that comprises a metal foil upper side and a metal foil underside, wherein the metal foil comprises a copper layer that has a copper layer upper side and a copper layer underside, wherein the metal foil upper side is formed by the copper layer upper side; and, a contacting layer that is arranged on the metal foil underside, and wherein the copper layer upper side has an oxygen content in the range of 10-30 atomic percent.

### CROSS-REFERENCE TO RELATED APPLICATION

This application claims priority pursuant to 35 U.S.C. 119 (a) to European Patent Application No. 25155317.8, filed Jan. 31, 2025, which application is incorporated herein by reference in its entirety.

### FIELD OF THE INVENTION

The present invention relates to a substrate arrangement, to a method for producing an electronic assembly and to an electronic assembly.

### BACKGROUND

In order to produce electronic assemblies, base substrates, in particular metal-ceramic substrates or lead frames, are often populated with electronic components, in particular semiconductor devices, in the field of power electronics.

Regions which have to be contacted electrically conductively with unpopulated regions of the base substrates are located on the upper side of the electronic components, which faces away from the base substrates. This contact usually takes place with bonding wires, wherein one end of the bonding wire is integrally bonded to a region on the upper side of the electronic component, while the other end of the bonding wire is integrally bonded to an unpopulated region of the base substrate. Bonding wires made of aluminum can be integrally bonded to the metal of the base substrates, in particular copper. Bonding wires made of aluminum, for example via a metal, usually silver-containing layer which is located on the upper side of the electronic components, can also be integrally bonded to the electronic components. However, bonding wires made of aluminum have the disadvantage of low electrical conductivity. Furthermore, it has been found that electrical contacting of electronic components and base substrates via bonding wires made of aluminum has only insufficient reliability and reduced functionality.

For this reason, there is a need to replace aluminum bonding wires with bonding wires made of copper. Copper has a very high electrical conductivity compared to aluminum. Furthermore, bonding wires made of copper can be connected particularly reliably in an integrally bonded manner to the metal of the base substrates, in particular copper. However, bonding wires made of copper cannot easily be connected to the upper side of the electronic components in an integrally bonded manner.

### SUMMARY

In the prior art, it is therefore proposed that bonding wires made of copper are not to be connected directly to the upper side of the electronic components. Instead, a substrate arrangement is provided that has a metal foil and a contacting layer (for example, a pre-dried sintering paste). The metal foil has an upper side and an underside, wherein the underside of the metal foil is bonded to the entire surface of the contacting layer. The metal foil of the substrate arrangement is finally integrally bonded to the upper side of the electronic component via the contacting layer, so that the upper side of the metal foil is available for an integrally bonded connection to the copper bonding wire.

The method therefore comprises a substrate arrangement with a metal foil, the upper side of which can be bonded to a copper bonding wire in a particularly stable manner and with consistently high quality.

Therefore, an object of the present invention is preferably to provide a substrate arrangement with a metal foil, the upper side of which can be bonded to a copper bonding wire in a particularly stable manner and with consistently high quality.

This object is achieved by the substrate arrangement according to claim 1.

The invention therefore provides a substrate arrangement comprising
(a) a metal foil that comprises a metal foil upper side and a metal foil underside, wherein the metal foil comprises a copper layer that has a copper layer upper side and a copper layer underside, wherein the metal foil upper side is formed by the copper layer upper side; and,
(b) a contacting layer that is arranged on the metal foil underside; characterized in that the copper layer upper side has an oxygen content in the range of 10-30 atomic percent.

The invention further provides a method for producing an electronic assembly, and an electronic component.

The invention relates to a substrate arrangement.

The electrical contacting of the upper side of an electronic component with unpopulated regions of base substrates can preferably be prepared with the substrate arrangement. For this purpose, the metal foil is connected in an integrally bonded manner to the upper side of the electronic component via the contacting layer. The metal foil in this case provides a surface which is suitable for forming a reliable integrally bonded connection to one end of a bonding wire, in particular a copper bonding wire. The other end of the bonding wire can be connected to an unpopulated region of a base substrate, so that an electrical contacting results between the upper side of the electronic component and an unpopulated region of a base substrate via the metal foil and the bonding wire.

The substrate arrangement has a metal foil.

The metal foil comprises a metal foil upper side and a metal foil underside. A contacting layer is arranged on the metal foil underside. In this case, the metal foil underside is at least regionally connected in a planar manner to the contacting layer. The metal foil underside is therefore preferably the surface of the metal foil with the greatest surface area which is connected in a planar manner to the contacting layer at least regionally. The metal foil upper side is therefore preferably the side, facing away from the contacting layer, of the metal foil. The metal foil upper side is therefore the side opposite the metal foil underside.

According to a preferred embodiment, the metal foil upper side does not form an integrally-bonded connection with a solid body. A solid body is preferably a body that is solid at a temperature of 25 °C and normal pressure. Preferably, the metal foil upper side does not form an integrally bonded connection with a layer of insulating material. Particularly preferably, the metal foil upper side does not form an integrally bonded connection with a ceramic layer.

According to a further preferred embodiment, less than 20 percent, more preferably less than 10 percent, even more preferably less than 5 percent, most preferably less than 1 percent and in particular less than 0.1 percent of the metal foil upper side, based upon the total surface of the metal foil upper side, is inseparably bonded to a solid body. Inseparably bonded preferably means that a release of the connection is not possible or would result in at least partial destruction of the metal foil upper side, or at least a functional impairment. The solid body can be a solid body comprising insulating material, particularly a ceramic body.

According to a further preferred embodiment, the metal foil upper side can be connected to a bonding wire, preferably a bonding wire comprising at least 50 wt. % copper.

The metal foil preferably has a thickness d (Me). The thickness d (Me) of the metal foil is preferably in the range of 5-500 μm, particularly preferably in the range of 10-200 μm and very particularly preferably in the range of 20-150 μm.

The metal foil comprises a copper layer.

The copper layer is preferably formed from a copper foil. The copper layer preferably comprises at least 99.5 wt. % copper, particularly preferably at least 99.95 wt. % copper, and very particularly preferably at least 99.995 wt. % copper, based upon the total weight of the copper layer.

The copper layer has a copper layer upper side and a copper layer underside. The metal foil upper side is formed by the copper layer upper side. The copper layer underside can be connected to another layer.

The metal foil can consist of a copper layer. In this case, the metal foil underside can be formed from the copper layer underside.

The copper layer upper side has an oxygen content in the range of 10-30 atomic percent. The copper layer upper side preferably has an oxygen content in the range of 12-28 atomic percent and particularly preferably an oxygen content in the range of 15-25 atomic percent.

In accordance with a preferred embodiment, the copper layer upper side has a carbon content in the range of 30-60 atomic percent. The copper layer upper side preferably has a carbon content in the range of 35-55 atomic percent and particularly preferably a carbon content in the range of 40-50 atomic percent.

In accordance with a preferred embodiment, the copper layer upper side is designed such that, in a depth profile measurement after sputtering for a sputtering time of 300 s (sputtering rate: 1.0 nm/min for the reference tantalum pentoxide; ion source: xenon ions, acceleration voltage: 4 kV), the exposed copper layer upper side has an oxygen content of less than 1.0 atomic percent.

In accordance with another preferred embodiment, the copper layer upper side is designed such that that, in a depth profile measurement after sputtering for a sputtering time of 180 s (sputtering rate: 1.0 nm/min for the reference tantalum pentoxide; ion source: xenon ions, acceleration voltage: 4 kV), the exposed copper layer upper side has an oxygen content of less than 1.0 atomic percent.

The content of copper, carbon and oxygen on the copper layer upper side is preferably determined by Auger electron spectroscopy. The measurement is preferably performed using the PHI 5800 MultiTechnique ESCA system (Physical Electronics, Inc., USA). The sample of the substrate arrangement to be measured is preferably first stored in a moisture barrier bag under a nitrogen atmosphere. For this purpose, after sampling, the sample is transferred to the moisture barrier bag and rinsed twice with nitrogen with a purity of 4 N. The bag is then sealed by welding. The moisture barrier bag is opened immediately before the measurement, and the sample contained therein is then placed into the measuring chamber of the PHI 5800 MultiTechnique ESCA system. In the measuring chamber, the content of copper, carbon and oxygen on the copper layer upper side is measured by means of Auger electron spectroscopy. The PHI 5800 MultiTechnique ESCA system is also preferably used for depth profile measurement. For this purpose, the copper layer upper side of the sample is sputtered for a defined time (for example 300 s or 180 s), and the content of copper, carbon and oxygen of the copper layer upper side exposed by sputtering is measured by means of Auger electron spectroscopy. The sputtering is preferably carried out with an ion gun (with xenon ions as the ion source) which is operated with an acceleration voltage of 4 kV at a sputtering rate of 1.0 nm/min against the reference tantalum pentoxide. The analysis parameters for Auger electron spectroscopy are preferably 5 kV at a beam current of 15 nA and a measurement spot of 100×100 μm. The signals obtained by Auger electron spectroscopy are preferably evaluated using the software: PHI MultiPak Version 9.9 (Physical Electronics, Inc., USA). The given values are preferably average values from five measurements at different regions of the substrate arrangement.

According to a preferred embodiment, the metal foil comprises an adhesion-promoting layer.

The adhesion-promoting layer is preferably a layer that enables or promotes adhesion of the contacting layer to the metal foil underside. The adhesion-promoting layer is preferably a layer that enables or promotes the formation of an integral connection between the substrate arrangement (in particular the metal foil underside of the substrate arrangement) and the upper side of an electronic component via the contacting layer.

The adhesion-promoting layer preferably has a thickness in the range of 20-1,500 nm, particularly preferably a thickness in the range of 30-100 nm, and very particularly preferably a thickness in the range of 50-500 nm.

The adhesion-promoting layer preferably has an adhesion-promoting layer upper side and an adhesion-promoting layer underside. The adhesion-promoting layer upper side is preferably integrally bonded to the copper layer underside. The adhesion-promoting layer upper side is preferably connected in a planar manner to the copper layer underside. Preferably, the contacting layer is arranged on the adhesion-promoting layer underside.

The adhesion-promoting layer preferably comprises a noble metal or a noble metal alloy. The noble metal is preferably selected from the group consisting of gold, silver and palladium. The noble metal alloy is preferably an alloy which contains at least one noble metal and at least one non-noble metal. The noble metal of the noble metal alloy is preferably selected from the group consisting of gold, silver, and palladium. The non-noble metal of the noble metal alloy is preferably nickel. The noble metal alloy is preferably selected from the group consisting of nickel-gold alloys, nickel-silver alloys, and nickel-palladium-gold alloys.

According to a particularly preferred embodiment, the adhesion-promoting layer is multi-layered. A multi-layer embodiment provides, for example, a nickel layer that is in contact with the copper layer underside, a palladium layer in contact with the nickel layer, and a gold layer in contact with the palladium layer.

The adhesion-promoting layer can be created, for example, by chemical (e.g., electrochemical) or physical deposition, in particular on the copper layer underside. The chemical deposition can be carried out, for example, galvanically or without external current.

In accordance with a further preferred embodiment, the metal foil has at least one through-opening. A through-opening is preferably understood to mean a recess in the material of the metal foil which extends from a first opening in the metal foil upper side up to a second opening in the metal foil underside. The openings can have different sizes and geometries. It can be preferable for the metal foil to have a plurality of through-openings. The through-openings can, for example, be cylindrical, round, rectangular, oval, elliptical or rectangular with rounded corners.

The presence of through-openings can be advantageous in particular if the substrate arrangement comprises a prefixing layer which contains a prefixing agent. In this case, components or residues of the prefixing agent can liquefy during a temperature application or pressure application, such as during a sintering process, and can be absorbed into the through-openings due to the capillary effect caused by the through-opening in order thereby to prevent an uncontrollable escape of portions or residues of the prefixing agent.

The substrate arrangement has a contacting layer.

The contacting layer is preferably a layer that can enable or promote the formation of an integral connection between the upper side of an electronic component, in particular the optionally metalized upper side of an electronic component, and the metal foil, in particular the metal foil underside.

The contacting layer is arranged on the metal foil underside. Preferably, the contacting layer is bonded to the metal foil underside in a planar manner.

The contacting layer preferably has a thickness in the range of 5-500 μm, particularly preferably a thickness in the range of 5-250 μm, and very particularly preferably a thickness in the range of 10-100 μm.

The contacting layer comprises a contacting means. The contacting means is preferably able to enter into an integrally bonded connection with the (optionally metalized) upper side of an electronic component.

The contacting member preferably comprises at least one ingredient which is selected from the group consisting of silver and copper.

According to a preferred embodiment, the contacting means comprises at least one element which is selected from the group consisting of sintering materials, solder materials, and adhesives.

The sintering material is preferably selected from the group consisting of sintering pastes, sintering films and sintering preforms.

According to a preferred embodiment the sintering material comprises a sintering paste. The sintering paste is preferably a sintering paste customary in the art. The sintering paste preferably comprises at least one metal which is selected from the group consisting of silver and copper, and an organic compound. It can be preferred for the metal in the sintering paste to be present in the form of particles. The particles can assume any shape and can therefore be present, for example, as spherical particles, flakes or irregularly shaped silver particles. The organic compound is preferably selected from the group consisting of dispersants, binders, fatty acids, and mixtures thereof. The dispersant can be selected from dispersants that are customary in the art. An exemplary dispersant is terpineol. The binders can be selected from polymers that are customary in the art. Examples include cellulose derivatives, for example methylcellulose, ethylcellulose, ethylmethylcellulose, carboxycellulolose and hydroxypropylcellulolose. The fatty acids can be selected from fatty acids that are customary in the art. The fatty acids are preferably selected from the group consisting of caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), arachidic acid (eicosanoic acid/icosanoic acid), behenic acid (docosanoic acid) and lignoceric acid (tetracosanoic acid).

According to a further preferred embodiment, the sintering material comprises a sintering film. Preferably, the sintering film is a sintering film customary in the art, as disclosed, for example, in European patent application EP3154729 A1. A sintering film can therefore have, for example, a sintering paste which comprises metal particles (in particular silver particles) and a binder which is present pre-dried on a carrier substrate. The sintering film can, for example, have a thickness ranging from 5-300 μm.

According to a further preferred embodiment, the sintering material comprises a sintering preform. Preferably, the sintering preform is a conventional sintering preform as disclosed, for example, in European Patent Application No. EP2428293 A2.

According to a preferred embodiment, the solder material comprises at least one solder paste. The solder paste is preferably a solder paste customary in the art. The solder paste preferably comprises a solder alloy and a flux. The solder alloy preferably comprises, as the main element (element having the greatest weight proportion), tin, particularly preferably at least one further element which is selected from the group consisting of copper and silver, and very particularly preferably at least one further element which is selected from the group consisting of bismuth, antimony, indium, germanium, cobalt, iron and nickel. The flux is preferably a flux customary in the art, particularly preferably an organic flux.

According to a preferred embodiment, the adhesive comprises a conductive adhesive. The conductive adhesive is preferably a conductive adhesive customary in the art. The conductive adhesive preferably comprises silver particles and an epoxy resin, which preferably cures at a temperature in the range of 120 °C-200 °C.

According to a particularly preferred embodiment, the contacting layer comprises a pre-dried sintering paste.

According to a preferred embodiment, the substrate arrangement comprises a prefixing layer.

The prefixing layer is preferably a layer that is bonded to the metal foil underside and/or the contacting layer. The metal foil underside is preferably formed by the copper foil underside or the adhesion-promoting layer. The prefixing layer can be, for example, a continuous layer or an interrupted layer. The dimension of the continuous layer is not further limited. For this reason, the continuous layer also comprises a punctiform layer. In the case of a continuous layer, the prefixing layer can be connected to the metal foil underside and/or the contacting layer in a planar manner. In the case of an interrupted layer, the prefixing layer can comprise for example a plurality of portions which are not in contact with one another and which are connected in a planar manner to the metal foil underside and/or the contacting layer. If the prefixing layer is connected to the metal foil underside, the contacting layer is connected in a planar manner to the metal foil underside preferably at least regionally, and the prefixing layer is connected to regions of the metal foil underside which are not connected in a planar manner to the contacting layer. In such a case, the contacting layer and the prefixing layer are each connected to the metal foil underside and are preferably arranged next to one another.

According to a preferred embodiment, the prefixing layer is formed as a continuous layer and is connected in a planar manner to the contacting layer so that at least 20%, more preferably at least 50%, particularly preferably at least 70%, very particularly preferably at least 98% and in particular 100% of the contacting layer is in contact with the prefixing layer.

According to a further preferred embodiment, the prefixing layer is formed as a continuous layer in a punctiform manner and is in contact with the contacting layer and/or with the metal foil underside.

According to a further preferred embodiment, the prefixing layer is formed as an interrupted layer comprising a plurality of portions which are not in contact with one another and which are in contact with the contacting layer and/or with the metal foil underside.

The prefixing layer preferably comprises a prefixing agent. The prefixing agent can serve to prefix the substrate arrangement on an electronic component so that the structure comprising the substrate arrangement and the electronic component has improved transportability—for example, at the location of the further processing. Preferably, the prefixing agent is a temporary or releasable fixing agent which allows at least a temporary fixing of the substrate arrangement to an electronic component. Suitable prefixing agents are described, for example, in European patent application EP3940758 A2.

The prefixing agent therefore preferably comprises at least one compound which is selected from the group consisting of thermoplastic polymers, inorganic filler particles, and organic solvents. According to a preferred embodiment, the prefixing agent comprises at least one thermoplastic polymer and particularly preferably at least one compound which is selected from the group consisting of inorganic filler particles and organic solvents.

The thermoplastic polymers preferably have a glass transition temperature in the range of 60-120 °C. The glass transition temperature is preferably determined by means of dynamic differential calorimetry (DDC) or by means of differential scanning calorimetry (DSC) at a heating rate of 10 °C/minute. The thermoplastic polymers can in particular be (meth)acrylic copolymers. The (meth)acrylic copolymers preferably have a molar mass in the range of 35,000-70,000 g/mol (Mw=35,000 to 70,000 g/mol). The molar mass is preferably determined by means of gel permeation chromatography (GPC). For the gel permeation chromatography, the following applies: polystyrene gel as stationary phase, tetrahydrofuran as mobile phase, polystyrene standards.

The inorganic filler particles are preferably particles comprising at least one element selected from the group consisting of aluminum oxide, silicon dioxide, titanium dioxide, zirconium silicate, calcium silicate, mica, kaolin, and α-boron nitride. The inorganic filler particles preferably have an average particle size (d50) in the range of 5-20 μm and particularly preferably in the range of 5-10 μm. The average particle size (d50) is preferably determined by means of a laser diffraction method.

The organic solvents preferably have a boiling point of not more than 285 °C. According to a preferred embodiment, the organic solvents are selected from the group consisting of aromatics, ketones, esters, glycol ethers and alcohols. According to a particularly preferred embodiment, the organic solvents are selected from the group consisting of toluene, xylene, methyl ethyl ketone, methyl isobutyl ketone, polyvinyl ethers, ethyl acetate, isobutyl acetate, dimethyl succinate, diethylene glycol monobutyl ether, benzyl alcohol, triphenyl compounds, dimethyl compounds, and terpineols. According to a very particularly preferred embodiment, the organic solvents are selected from the group of terpineols.

According to a preferred embodiment, the substrate arrangement is suitable for connection to at least one electronic component. According to a particularly preferred embodiment, the substrate arrangement is suitable for connecting the metal foil to at least one electronic component.

An electronic component is preferably understood to mean an electronic or electrical part. The electronic component is preferably selected from the group consisting of semiconductor devices. The semiconductor devices are preferably selected from the group consisting of transistors, diodes, and integrated circuits.

According to a preferred embodiment, the electronic component comprises a metal upper-side coating. The metal upper-side coating can serve to make possible an easier connection of the metal foil via the contacting layer to the upper side of the electronic component. It may therefore be preferred that the upper side of the electronic component is created by the metal upper-side coating. The metal upper-side coating of the electronic component preferably comprises at least one element which is selected from the group consisting of nickel, palladium, silver, copper, and gold. According to a preferred embodiment, the electronic component comprises a metal underside coating. The metal underside coating can serve to enable an easier connection of the base substrate to the underside of the electronic component. It may therefore be preferred that the underside of the electronic component is created by the metal underside coating. The metal underside coating of the electronic component preferably comprises at least one noble metal. According to a preferred embodiment, the metal underside coating of the electronic component comprises at least one element which is selected from the group consisting of gold, silver, aluminum, titanium, and nickel, and very particularly preferably silver.

The electrical contacting of the upper side of the electronic component with unpopulated regions of base substrates can preferably be prepared with the substrate arrangement. For this purpose, the metal foil of the substrate arrangement is connected in an integrally-bonded manner to the upper side of the electronic component via the contacting layer. The metal foil provides a surface which is suitable for the integrally-bonded connection to a bonding wire, in particular a copper bonding wire, in a particularly stable manner and with consistently high quality. Surprisingly, it has been found that the upper side of the metal foil of the substrate arrangement can be bonded to a copper bonding wire in a particularly stable and consistently high-quality manner when the metal foil comprises a copper layer with a copper upper side that has an oxygen content in the range of 10-30 atomic percent. Without wishing to be bound to an explanation, this effect could be due to the fact that an oxygen content in this region prevents the uncontrolled formation of thicker copper oxide layers, which could impair bondability. With an oxygen content of less than 10 atomic percent, this protective layer effect could no longer be achieved to a sufficient degree. However, at an oxygen content higher than 30 atomic percent, a thick copper oxide layer may already have formed, which impairs bondability.

The method for producing the substrate arrangement according to the invention is not further limited.

According to a preferred embodiment, the method for producing the substrate arrangement according to the invention comprises the steps of:
(A) providing a metal foil that comprises a metal foil upper side and a metal foil underside, wherein the metal foil comprises a copper layer that has a copper layer upper side and a copper layer underside, wherein the metal foil upper side is formed by the copper layer upper side, and wherein the copper layer upper side has an oxygen content in the range of 10-30 atomic percent;
(B) providing a contacting means; and,
(C) applying the contacting means to the metal foil underside to form a contacting layer.

In step (A) of the method, a metal foil is provided that comprises a metal foil upper side and a metal foil underside, wherein the metal foil comprises a copper layer that has a copper layer upper side and a copper layer underside, wherein the metal foil upper side is formed by the copper layer upper side, and wherein the copper layer upper side has an oxygen content in the range of 10-30 atomic percent. The metal foil is preferably a metal foil as described elsewhere herein.

The metal foil can, for example, be purchased commercially or produced in a conventional manner. The copper layer upper side of the metal foil—for example, commercially purchased or manufactured—may already have the required or preferred properties with regard to the oxygen content and/or carbon content. Alternatively, the oxygen content can be adjusted in the usual manner in the art.

In accordance with one embodiment, the metal foil can be subjected to controlled heat treatment and conditioning to adjust the oxygen content of the copper layer upper side. To this end, the metal foil can for example be first exposed to a temperature ranging from 300-600 °C, particularly preferably to a temperature ranging from 350-550 °C and most preferably to a temperature ranging from 400-500 °C. The exposure to this temperature preferably takes place for a period of 30 min to 10 h, particularly preferably for a period of 1 to 7 h, and most preferably for a period of 2 to 5 h. The heat treatment preferably takes place in an inert or reducing atmosphere, for example in an atmosphere of process gas (95% nitrogen, 5% hydrogen). The metal foil is then preferably cooled down, for example to room temperature. After the heat treatment, conditioning is preferably carried out to avoid the formation of a high proportion of copper oxide and a thick copper oxide layer. The conditioning preferably takes place immediately after the cooling of the metal foil. For this purpose, the metal foil is preferably stored in an inert atmosphere with a low residual moisture content. The inert atmosphere can, for example, be a nitrogen atmosphere. The residual moisture content can preferably lie in the range of 0.2-1.0%, particularly preferably a range of 0.3-0.7%, and most preferably in the range of 0.5-0.6%. Storage preferably takes place for a period of 10 min-100 h, particularly preferably for a period of 30 min-50 h and most preferably for a period of 10-40 h.

In accordance with another embodiment, the oxygen content of the copper layer upper side can be adjusted in an alternative way. For example, the copper layer upper side can be treated with an oxidizing agent in a suitable manner. Alternatively, the surface of the copper layer upper side can first be extensively oxidized by heat treatment in an oxidizing atmosphere or by treatment with an oxidizing agent, wherein treatment with a reducing agent follows to adjust the copper layer upper side to the target value for the oxygen content. Furthermore, it is possible to subject the copper layer upper side to plasma treatment to adjust the oxygen content.

To adjust the carbon content of the copper layer upper side, the copper layer upper side can be treated, for example, with an organic compound that can also be used to adjust the oxygen content (for example, citric acid or benzotriazole).

Providing a contacting means occurs in step (B) of the method.

The contacting means is preferably a contacting means as described elsewhere herein.

In step (C) of the method, the contacting means is applied to the metal foil underside, forming a contacting layer.

Applying the contacting material to the metal foil underside to form a contacting layer can be carried out by methods customary in the art. Preferably, the contacting material is applied by jetting, dispensing, spraying, brushing, dabbing, dipping, or printing, in particular screen printing or stencil printing or by lamination.

According to a preferred embodiment, in a further step (D), a prefixing agent is applied to the metal foil underside and/or the contacting layer, forming a prefixing layer, wherein the prefixing layer is at least partially bonded to the metal foil underside and/or the contacting layer over a planar area. The prefixing agent is preferably a prefixing agent as described elsewhere herein. The prefixing agent can be applied to the metal foil underside and/or contacting layer by methods customary in the art. Preferably, the prefixing agent is applied by jetting, dispensing, spraying, brushing, dabbing, dipping or printing, in particular screen printing or stencil printing.

In accordance with a preferred embodiment, in a further step (E) of the method, the contacting means, particularly preferably the sintering material and most preferably the sintering paste, is pre-dried. The pre-drying can serve to at least partially remove volatile constituents contained in the contacting material, such as organic compounds, for example. The pre-drying can take place, for example, at a temperature in the range of 80-150 °C and, for example, for a period of 2-30 minutes. The pre-drying usually results in a volume shrinkage, so that the thickness of the contacting layer is also reduced.

According to a further preferred embodiment, pre-drying of the prefixing agent, if available, takes place in a further step (F) of the method. The pre-drying can serve to at least partially remove volatile constituents contained in the prefixing agent, such as organic compounds, for example. The pre-drying can take place, for example, at a temperature in the range of 80-150 °C and, for example, for a period of 2-30 minutes. The pre-drying usually results in a volume shrinkage, so that the thickness, of the prefixing layer is also reduced. Steps (E) and (F) can also coincide.

The method yields a substrate arrangement with a metal foil, the upper side of which can be bonded with a copper bonding wire in a particularly stable manner and with consistently high quality.

The invention relates to a method for producing an electronic assembly.

The method comprises the following steps:
(A) providing a base substrate that comprises an upper side, wherein the base substrate comprises a metal layer;
(B) providing an electronic component that comprises an upper side and an underside;
(C) providing a substrate arrangement described herein;
(D) contacting the upper side of the base substrate with the underside of the electronic component, forming an integrally bonded connection; and,
(E) contacting the upper side of the electronic component with the contacting layer of the substrate arrangement, forming an integrally bonded connection.

In step (A) of the method, a base substrate is provided. The base substrate comprises a metal layer. Furthermore, the base substrate has an upper side.

For example, the metal layer of the base substrate can comprise copper or aluminum. Preferably, the metal layer of the base substrate can be formed from a metal foil. According to a preferred embodiment, the metal layer of the base substrate comprises a copper foil.

According to a preferred embodiment, the base substrate consists of the metal layer. According to another preferred embodiment, the base substrate comprises a metal layer and a layer of insulating material. According to a further preferred embodiment, the base substrate comprises a metal layer and a layer of insulating material which are connected to one another in an integrally bonded manner. The base substrate preferably comprises a layer of insulating material which, on a first side and a second side facing away from the first side, is connected in an integrally bonded manner to a metal layer. The insulating material of the base substrate is preferably selected from the group consisting of glass and ceramic. The ceramic can, for example, be selected from the group consisting of oxide ceramics, nitride ceramics, and carbide ceramics.

According to a preferred embodiment, the base substrate is selected from the group consisting of metal-ceramic substrates, printed circuit boards (PCBs) and leadframes. According to a particularly preferred embodiment, the base substrate is a metal-ceramic substrate customary in the art. The metal-ceramic substrate is preferably selected from the group consisting of DCB (direct copper bonded) substrates and AMB (active metal brazed) substrates.

The upper side of the base substrate is preferably created by the metal layer.

In step (B) of the method, an electronic component is provided. The electronic component has an upper side and an underside.

The electronic component is preferably an electronic component as described elsewhere herein.

In step (C) of the method, a substrate arrangement is provided.

The substrate arrangement is preferably a substrate arrangement as described elsewhere herein.

The substrate arrangement therefore preferably has
(a) a metal foil that comprises a metal foil upper side and a metal foil underside, wherein the metal foil comprises a copper layer that has a copper layer upper side and a copper layer underside; wherein the metal foil upper side is formed by the copper layer upper side; and,
(b) a contacting layer that is arranged on the metal foil underside, wherein the copper layer upper side has an oxygen content in the range of 10-30 atomic percent.

In step (D) of the method, the upper side of the base substrate is contacted with the underside of the electronic component, forming an integrally bonded connection.

For this purpose, the base substrate and the electronic component are preferably positioned such that the underside of the electronic component is in contact with the upper side of the base substrate preferably via a contacting material. The contacting means can be, for example, a sintering paste, a soldering paste or a conductive adhesive. The structure comprising the base substrate and the electronic component is subsequently subjected to a treatment which allows an integrally bonded connection through the contacting material. The underside of the electronic component is fastened here to the upper side of the base substrate. The treatment is preferably carried out by introducing energy. The introduction of energy can preferably take place in the form of temperature application and particularly preferably in the form of temperature and pressure application.

In step (E) of the method, the upper side of the electronic component is contacted with the contacting layer of the substrate arrangement, forming an integrally bonded connection. In this case, the formation of an integrally bonded connection is preferably carried out between the upper side of the electronic component and the metal foil of the substrate arrangement.

For this purpose, the substrate arrangement and the electronic component are preferably positioned such that the contacting layer of the substrate arrangement is in contact with the upper side of the electronic component. The structure comprising the substrate arrangement and the electronic component is subsequently subjected to a treatment which allows an integrally bonded connection through the contacting layer. The metal foil of the substrate arrangement is fastened here to the upper side of the electronic component. The treatment is preferably carried out by introducing energy. The introduction of energy can preferably take place in the form of temperature application and particularly preferably in the form of temperature and pressure application.

Steps (D) and (E) can be carried out in one manufacturing step or in different manufacturing steps. In this case, steps (D) and (E) can be carried out sequentially or simultaneously.

If steps (D) and (E) are carried out sequentially, step (D) can take place before step (E). On the other hand, it is also possible for step (E) to take place before step (D).

If steps (D) and (E) are carried out sequentially, according to a first embodiment in step (D) the electronic component can be part of a first arrangement which comprises the electronic component and the metal foil of the substrate arrangement. In this case, a first arrangement, which comprises the electronic component and the metal foil of the substrate arrangement, can first be produced in step (E) by contacting the upper side of the electronic component with the metal foil of the substrate arrangement to form an integrally bonded connection between the upper side of the electronic component and the metal foil of the substrate arrangement. This first arrangement can then be contacted with the base substrate in step (D) so that the underside of the electronic component is connected in an integrally bonded connection to the upper side of the base substrate as part of the first arrangement.

If steps (D) and (E) are carried out sequentially, according to a second embodiment in step (E) the electronic component can be part of a second arrangement which comprises the base substrate and the electronic component. In this case, a second arrangement which comprises the base substrate and the electronic component can first be produced in step (D). This second arrangement can then be contacted with the substrate arrangement in step (E) so that the metal foil of the substrate arrangement is connected in an integrally bonded manner to the upper side of the electronic component as part of the second arrangement.

By means of the integrally bonded connection of the base substrate, electronic component and metal foil of the substrate arrangement, an electronic assembly is obtained.

According to a preferred embodiment, in a further step (F) a region on the upper side of the metal foil is electrically contacted with a region on the upper side of the base substrate.

The electrical contacting preferably takes place by wire bonding. A bonding wire is preferably used for the wire bonding. The term bond wire comprises wires suitable for bonding, preferably regardless of their diameter or thickness, and particularly preferably regardless of their cross-sectional geometry (thus, for example, also as bond tapes). The bonding wire preferably comprises copper. According to a preferred embodiment, the bonding wire is made of a material selected from the group consisting of copper and copper alloys.

### BRIEF DESCRIPTION OF THE DRAWINGS

Further features and advantages of the invention can be found in the following description of the figures, in which preferred embodiments of the invention are explained with reference to schematic drawings.

In the drawings:

FIG. 1 shows the side view of a substrate arrangement according to the invention; and

FIG. 2 shows the side view of an electronic assembly which is obtained using the substrate arrangement according to the invention.

### DETAILED DESCRIPTION OF THE INVENTION

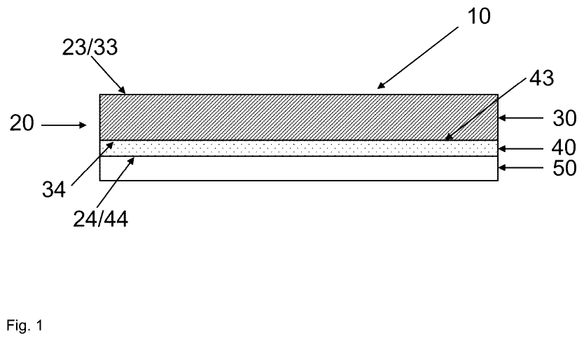

FIG. 1 shows—not to scale—a substrate arrangement 10 according to the invention, which comprises a metal foil 20 and a contacting layer 50. The metal foil 20 comprises a metal foil upper side 23 and a metal foil underside 24. The metal foil 20 is formed from a copper layer 30 and an adhesion-promoting layer 40. The copper layer 30 has a copper layer upper side 33 and a copper layer underside 34. The copper layer upper side 33 has an oxygen content in the range of 10-30 atomic percent. The adhesion-promoting layer 40 has an adhesion-promoting layer upper side 43 and an adhesion-promoting layer underside 44. The adhesion-promoting layer upper side 43 is integrally bonded to the copper layer underside 34. The metal foil upper side 23 is formed by the copper layer upper side 33. The metal foil underside 24 is formed by the adhesion-promoting layer underside 44. The contacting layer 50 is arranged on the metal foil underside 24 or the adhesion-promoting layer underside 44.

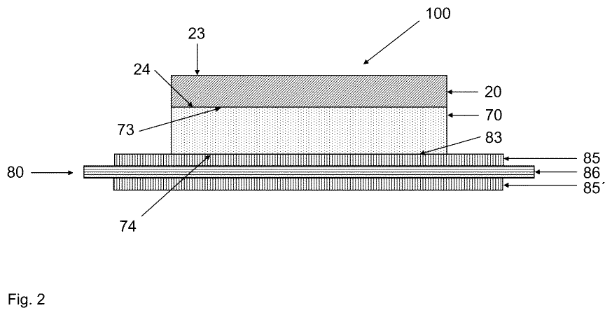

FIG. 2 shows an electronic assembly 100 which can be produced by the method according to the invention. The electronic assembly 100 comprises a metal foil 20, an electronic component 70, and a base substrate 80. The base substrate 80 has a layer of insulating material 86 which is connected on both sides to a metal layer 86, 86′ in a planar manner. The base substrate 80 is typically a metal-ceramic substrate. The upper side 83 of the base substrate 80 is created by the metal layer 85. An electronic component 70, which has an upper side 73 and an underside 74, is arranged on the upper side 83 of the base substrate 80. The underside 74 of the electronic component 70 is arranged on the upper side 83 of the base substrate 80. The electronic component 70 is connected to the base substrate 80 in a planar manner. For this purpose, the electronic component 70 can be fastened to the base substrate 80, for example using a sintering paste. A bonding zone (not shown) can therefore be located between the upper side 83 of the base substrate 80 and the underside 74 of the electronic component 70. The electronic component 70 is connected to a metal foil 20 via a bonding zone (not shown). The metal foil 20 has a metal foil upper side 23 and a metal foil underside 24. The metal foil underside 24 is arranged on the upper side 73 of the electronic component 40. The metal foil 20 is fastened to the electronic component 70. The fastening can take place by first positioning a substrate arrangement (as shown in FIG. 1) that comprises the metal foil 20 and a contacting layer on the upper side 73 of the electronic component 70 such that the contacting layer is in contact with the upper side 73 of the electronic component 70. The structure thus obtained is then exposed to conditions which enable the formation of an integrally bonded connection between the metal foil 20 and the electronic component 70. The contacting layer can consist, for example, of a pre-dried sintering paste. In this case, the structure is subjected, for example, to temperature and pressure in order to enable the formation of a sintered connection between the metal foil 20 and the electronic component 70. During the formation of the sintered connection, the bonding zone is created between the metal foil 20 and the electronic component 70 by the contacting layer (not shown). The metal foil upper side can be contacted with a bonding wire, with unpopulated regions on the upper side 83 of the base substrate 80 (not shown).

The metal foil upper side can also be connected in an integrally-bonded manner to a further component, in particular using a sintering material (not shown).

### EXAMPLES

The present invention is further illustrated below using examples which are, however, not to be understood as limiting.

### 1. PRODUCTION OF SUBSTRATE ARRANGEMENTS

Copper foils having a thickness of 50 μm were used to produce a substrate arrangement according to the Examples and the Comparative Examples. These copper foils were structured by means of photolithographic etching using a suitable masking with an iron chloride (FeCl₃) etching solution into copper foil pieces of the dimensions 7.6 mm×7.6 mm, wherein the individual copper foil pieces were still connected to one another via struts. The masking was then removed.

### Example 1

The copper foil pieces were heat-treated in a batch oven at a temperature of 450 °C. For this purpose, the annealing chamber was first purged with process gas (mixture of 5% hydrogen and 95% nitrogen) after the introduction of the copper foil pieces. This process gas treatment was carried out for a duration of 30 min at a gas flow of 16 L/min (residual oxygen content ≤0.2%). The oven was then heated at a heating rate of 1 °C/min until a temperature of 450 °C was reached. After 3 h of treatment, the oven was switched off and allowed to cool down. After reaching room temperature, the gas flow was stopped, and the copper foil pieces were removed.

These were then subjected to a conditioning step. For this purpose, the copper foil pieces were stored in a drying cabinet at a temperature of 25 °C in a nitrogen atmosphere with a residual moisture of 0.5-0.6% for a period of 24 hours.

The copper foil pieces were then applied to a transfer foil (chip-cutting foil) in a plastic frame and metalized with a 400-nm-thick, electroplated contacting layer. A silver sintering layer was then applied to this contacting layer. For this purpose, a sintering paste (ASP 043-60, Heraeus) was applied by means of stencil printing to a region of 7.1 mm×7.1 mm (wet layer thickness=40 μm). In addition to the region covered with sintering paste, the coating had a peripheral edge region of 0.25 mm width that was free of sintering paste. The copper foil pieces provided with a sintering paste on the coating were then dried in an air atmosphere for ten minutes at 110 °C, removed from the frame, detached from the transfer film, and separated by laser by separating the struts, wherein substrate arrangements were obtained that have a metal foil comprising a metal foil upper side and metal foil underside, as well as a contacting layer, wherein the contacting layer was arranged on the metal foil underside.

### Example 2

Example 2 was carried out analogously to Example 1, wherein the copper foil pieces were stored in a drying cabinet at a temperature of 25 °C in a nitrogen atmosphere with a residual moisture of 0.5-0.6% for a period of 20 h during the conditioning step. The copper foil pieces were further processed directly.

### Example 3

Example 3 was carried out analogously to Example 1, wherein the copper foil pieces were stored in a drying cabinet at a temperature of 25 °C in a nitrogen atmosphere with a residual moisture of 0.5-0.6% for a period of 15 h during the conditioning step. The copper foil pieces were further processed directly.

### Example 4

Example 4 was carried out analogously to Example 1, wherein the copper foil pieces were stored in a drying cabinet at a temperature of 25 °C in a nitrogen atmosphere with a residual moisture of 0.5-0.6% for a period of 10 h during the conditioning step. The copper foil pieces were further processed directly.

### Example 5

Example 5 was carried out analogously to Example 1, wherein the copper foil pieces were stored in a drying cabinet at a temperature of 25 °C in a nitrogen atmosphere with a residual moisture of 0.5-0.6% for a period of 30 min during the conditioning step. The copper foil pieces were further processed directly.

### Comparative Example 1

Comparative example 1 was carried out analogously to example 1, wherein however no conditioning step was performed. The copper foil pieces were further processed directly.

### Comparative Example 2

Comparative example 2 was carried out analogously to example 1, wherein however no conditioning step was performed, and the foil pieces were stored for 96 hours at room temperature (24 °C) under a standard atmosphere (air) before further processing.

### 2. PRODUCTION OF ELECTRONIC ASSEMBLIES

To produce electronic assemblies, arrangements consisting of a base substrate and an electronic component each were first created. A commercially available direct-metalized copper-ceramic substrate (DCB; Condura® classic, Heraeus) and, as an electronic component, a silicon chip having the dimensions 8.8 mm×8.8 mm (thickness=70 μm), which had a metalization (NiP/Pd) on the underside and a metalization (NiP/Pd) on the upper side, was used as the base substrate.

A sintering paste (ASP 338-28, Heraeus) was applied to the upper side of the copper-ceramic substrate by means of stencil printing (wet layer thickness=100 μm). The copper-ceramic substrate provided with sintering paste was dried at 100 °C for ten minutes in an air atmosphere and then cooled. The silicon chip was positioned on the pre-dried sintering paste, such that the underside of the silicon chip was in contact with the upper side of the corresponding copper-ceramic substrate.

Subsequently, the respective substrate arrangements in accordance with Examples 1 to 5 as well as the Comparative Examples 1 and 2 were positioned on each upper side of the silicon chip, so that the silver sintering layer of the corresponding substrate arrangement was in contact with the upper side of the silicon chip.

The corresponding structure obtained was then sintered. Sintering was carried out in a sintering press (Pink, Wertheim) for a duration of three minutes in a nitrogen atmosphere at a pressure of 20 MPa and a temperature of 250 °C. This resulted in electronic assemblies that were each equipped with metal foils from the substrate arrangements in accordance with Examples 1 to 5, or with metal foils from the substrate arrangements according to Comparative Examples 1 and 2.

Subsequently, a copper bonding wire with a diameter of 400 μm (Power Cu Soft, Heraeus) was bonded to the upper side of the metal foil of the produced electronic assemblies. For this purpose, the copper bonding wire was bonded to the upper side of the metal foil of the electronic assembly in a wedge-wedge bonding method with a wedge bonder (Asterion Orthodyne Bonder, Kulicke & Soffa) at a frequency of 80 KHz.

### 3. EVALUATION

3.1 Determination of the Oxygen and Carbon Content in the Copper Layer Upper Side of the Substrate Arrangements (without and with Sputtering)

The oxygen content and carbon content in the copper layer upper side of the metal foils of the electronic assemblies produced with the substrate arrangements of Examples 1-5 and the comparison examples 1 and 2 were determined by Auger electron spectroscopy.

The measurement was performed using the PHI 5800 MultiTechnique ESCA system (Physical Electronics, Inc., USA). The substrate arrangements to be measured were introduced into the measuring chamber of the PHI 5800 MultiTechnique ESCA system after being rinsed twice with nitrogen with a purity of 4 N. In the measuring chamber, the content of copper and oxygen on the copper layer upper side is measured by means of Auger electron spectroscopy. The PHI 5800 MultiTechnique ESCA system was also used for the depth profile measurements. For this purpose, the copper layer upper side of the sample was sputtered for 180 s and 300 s, and the copper and oxygen content of the copper layer upper side was measured using Auger electron spectroscopy. Sputtering was performed using an ion gun (with xenon ions as the ion source) which was operated with an acceleration voltage of 4 kV at a sputtering rate of 1.0 nm/min against the reference tantalum pentoxide. The analysis parameters for Auger electron spectroscopy were 5 kV at a beam current of 15 nA and a measurement spot of 100×100 μm. The signals obtained by Auger electron spectroscopy were evaluated using the software: PHI MultiPak Version 9.9 (Physical Electronics, Inc., USA). The determination was carried out in five different regions of the substrate arrangement. The respective average values of the five measurements are given in Table 1.

### 3.2 Evaluation of Bonding Results

The metal foils of the electronic assemblies produced with the substrate arrangements of examples 1-5 and the comparative examples 1 and 2 were then examined as to whether the upper side of the metal foil can be bonded to a copper bonding wire in a particularly stable manner and with consistently high quality. For this purpose, the electronic assemblies produced with the substrate arrangements of examples 1-5 and the comparative examples 1 and 2 and provided with a bonding wire were subjected to a mechanical pull test in accordance with the DVS leaflet 2811 (Deutscher Verband für Schweißen und verwandte Verfahren e. V.). The pull test examined the connection of the bonding wire to the metal foil surface of the electronic assembly. The pull test was performed with an XYTEC Condor Sigma pull tester (xyztec bv), which was equipped with a force transducer (10 kg) and a pull hook (1200 μm). The evaluation of the bonding results is carried out in accordance with DVS leaflet 2811 (Deutscher Verband für Schweißen und verwandte Verfahren e. V.) as follows:
“−−”: Bond does not adhere to the copper surface (so-called “wedge lift off”).
“−”: Wire break in the region of the transition from bond connection to wire region (so-called “heel break”) with greatly reduced pull force (<10 N).
“+”: Wire break in the region of the transition from bond connection to wire region (so-called heel break) with slightly reduced pull force (10-15 N).
“++”: Wire break with high pull force (>20N).
   The results are shown in Table 1.

TABLE 1
Results of the examination of the substrate arrangements
of Examples 1-5 and Comparative Examples 1-2.

| | Element content in at. % (O: oxygen, C: carbon) | | | | | | |
|---|---|---|---|---|---|---|---|
| | Sputtering | | | | | | |
| | — | — | 180 s | 180 s | 300 s | 300 s | |
| | O | C | O | C | O | C | Bonding result |
| Example 1 | 15 | 40 | <1 | <1 | <1 | <1 | ++ |
| Example 2 | 17 | 45 | <1 | <1 | <1 | <1 | ++ |
| Example 3 | 20 | 41 | <1 | <1 | <1 | <1 | ++ |
| Example 4 | 23 | 38 | 1 | <1 | <1 | <1 | ++ |
| Example 5 | 27 | 30 | 10 | <1 | <1 | <1 | + |
| Comparative | 32 | 39 | 15 | 3 | 5 | <1 | Mostly “−−,” |
| Example 1 | | | | | | | locally highly |
| | | | | | | | variable |
| Comparative | 35 | 28 | 15 | <1 | 10 | <1 | Mostly “−−,” |
| Example 2 | | | | | | | locally highly |
| | | | | | | | variable |

### 3.3 Assessment

The results show that with the substrate arrangements of Examples 1-5 according to the invention, a particularly stable bond of a copper bonding wire to the upper side of the metal foil of the substrate arrangements can be achieved. This bond is more stable and of the same quality than a bond that was obtained with the substrate arrangements of Comparative Examples 1 and 2. In particular, the upper side of the metal foil has a homogeneous composition that enables the formation of a stable bond with equally high quality.

### REFERENCE NUMERALS

10 Substrate arrangement
20 Metal foil
23 Metal foil upper side
24 Metal foil underside
30 Copper layer
33 Copper layer upper side
34 Copper layer underside
40 Adhesion-promoting layer
43 Adhesion-promoting layer upper side
44 Adhesion-promoting layer underside
50 Contacting layer
70 Electronic component
73 Upper side (electronic component)
74 Underside (electronic component)
80 Base substrate
83 Upper side (base substrate)
85, 85′ Metal layer
86 Layer of insulating material
100 Electronic assembly

What is claimed is:

1. A substrate arrangement comprising:
(a) a metal foil that comprises a metal foil upper side and a metal foil underside, wherein the metal foil comprises a copper layer that has a copper layer upper side and a copper layer underside, wherein the metal foil upper side is formed by the copper layer upper side; and,
(b) a contacting layer that is arranged on the metal foil underside, wherein the copper layer upper side has an oxygen content in the range of 10-30 atomic percent.

2. The substrate arrangement according to claim 1, wherein the copper layer upper side has a carbon content in the range of 30-60 atomic percent.

3. The substrate arrangement according to claim 1, wherein the copper layer upper side is designed such that, in a depth profile measurement after sputtering for a sputtering time of 300 s (sputtering rate: 1.0 nm/min for the reference tantalum pentoxide; ion source: xenon ions, acceleration voltage: 4 kV), the exposed copper layer upper side has an oxygen content of less than 1.0 atomic percent.

4. The substrate arrangement according to claim 1, wherein the metal foil comprises an adhesion-promoting layer that has an adhesion-promoting layer upper side and an adhesion-promoting layer underside, wherein the adhesion-promoting layer upper side is integrally bonded to the copper layer underside.

5. The substrate arrangement according to claim 4, wherein the adhesion-promoting layer is multi-layered.

6. The substrate arrangement according to claim 1, wherein the contacting layer comprises a contacting means.

7. The substrate arrangement according to claim 6, wherein the contacting means comprises at least one member selected from the group consisting of silver and copper.

8. The substrate arrangement according to claim 6, wherein the contacting means comprises a sintering material.

9. The substrate arrangement according to claim 8, wherein the contacting layer comprises a pre-dried sintering paste.

10. A method for producing an electronic assembly comprising the steps of:
(A) providing a base substrate that comprises an upper side, wherein the base substrate comprises a metal layer;
(B) providing an electronic component that comprises an upper side and an underside;
(C) providing a substrate arrangement according to claim 1;
(D) contacting the upper side of the base substrate with the underside of the electronic component, forming an integrally bonded connection; and,
(E) contacting the upper side of the electronic component with the contacting layer of the substrate arrangement, forming an integrally bonded connection.

11. An electronic assembly which can be produced by a method according to claim 10.

12. The substrate arrangement according to claim 2, wherein the copper layer upper side is designed such that, in a depth profile measurement after sputtering for a sputtering time of 300 s (sputtering rate: 1.0 nm/min for the reference tantalum pentoxide; ion source: xenon ions, acceleration voltage: 4 kV), the exposed copper layer upper side has an oxygen content of less than 1.0 atomic percent.

13. The substrate arrangement according to claim 2, wherein the metal foil comprises an adhesion-promoting layer that has an adhesion-promoting layer upper side and an adhesion-promoting layer underside, wherein the adhesion-promoting layer upper side is integrally bonded to the copper layer underside.

14. The substrate arrangement according to claim 3, wherein the metal foil comprises an adhesion-promoting layer that has an adhesion-promoting layer upper side and an adhesion-promoting layer underside, wherein the adhesion-promoting layer upper side is integrally bonded to the copper layer underside.

15. The substrate arrangement according to claim 2, wherein the contacting layer comprises a contacting means.

16. The substrate arrangement according to claim 3, wherein the contacting layer comprises a contacting means.

17. The substrate arrangement according to claim 4, wherein the contacting layer comprises a contacting means.

18. The substrate arrangement according to claim 5, wherein the contacting layer comprises a contacting means.

19. The substrate arrangement according to claim 7, wherein the contacting means comprises a sintering material.

20. A method for producing an electronic assembly comprising the steps of:
(A) providing a base substrate that comprises an upper side, wherein the base substrate comprises a metal layer;
(B) providing an electronic component that comprises an upper side and an underside;
(C) providing a substrate arrangement according to claim 2;
(D) contacting the upper side of the base substrate with the underside of the electronic component, forming an integrally bonded connection; and,
(E) contacting the upper side of the electronic component with the contacting layer of the substrate arrangement, forming an integrally bonded connection.
